(19) United States
(12) Patent Application Publication
(10) Pub. No.: US 2025/0374572 A1
(43) Pub. Date: Dec. 4, 2025

(54) SEMICONDUCTOR DEVICE

(71) Applicant: Mitsubishi Electric Corporation, Tokyo (JP)

(72) Inventors: Masanori TSUKUDA, Tokyo (JP); Masaki SUDO, Tokyo (JP); Kakeru OTSUKA, Tokyo (JP); Yosuke NAKATA, Tokyo (JP); Kazuya KONISHI, Tokyo (JP)

(73) Assignee: Mitsubishi Electric Corporation, Tokyo (JP)

(21) Appl. No.: 19/067,751

(22) Filed: Feb. 28, 2025

(30) Foreign Application Priority Data
Jun. 4, 2024 (JP) 2024-090469

(51) Int. Cl. H10D 12/00

(52) U.S. Cl. CPC H10D 12/416; H10D 12/415; H10D 12/481

(57) ABSTRACT

A semiconductor device includes: a first main surface-side gate structure provided in a first main surface to control a first conductive channel in a base layer; and a second main surface-side gate structure provided in a second main surface to control a second conductive channel in a first collector layer, and a first dense region in which three or more consecutive second main surface-side gate structures are arranged and a first sparse region in which three or more consecutive second main surface-side gate structures are arranged at a density lower than that in the first dense region are defined.

### BACKGROUND

### Technical Field

The present disclosure relates to semiconductor devices.

### Description of the Background Art

An insulated gate bipolar transistor (IGBT) in which gate structures are provided in opposite surfaces (both surfaces) of a semiconductor substrate has been proposed in recent years. For example, in technology disclosed in Japanese Patent Application Laid-Open No. 2021-82725, a plurality of gate structures are provided on a side closer to a front surface of a semiconductor substrate, and a plurality of gate structures every two of which are proximate to each other are provided on a side closer to a back surface of the semiconductor substrate.

In conventional technology, however, only one of a region that tends to serve as an IGBT and a region that tends to serve as a diode is provided, or each region is small so that it is difficult to inject carriers into the region. There is thus room for improvement in power loss.

### SUMMARY

The present disclosure has been conceived in view of a problem as described above, and it is an object of the present disclosure to provide technology enabling suppression of power loss.

A semiconductor device according to the present disclosure includes: a semiconductor substrate having a first main surface and a second main surface opposite the first main surface, the semiconductor substrate including a drift layer of a first conductivity type between the first main surface and the second main surface; a base layer of a second conductivity type provided on a side closer to the first main surface of the drift layer; a source layer of the first conductivity type provided on a side closer to the first main surface of the base layer; a first main surface-side gate structure provided in the first main surface to control a first conductive channel in the base layer; a first collector layer of the second conductivity type provided on a side closer to the second main surface of the drift layer; a second collector layer of the first conductivity type provided on a side closer to the second main surface of the first collector layer; and a second main surface-side gate structure provided in the second main surface to control a second conductive channel in the first collector layer, wherein the second main surface-side gate structure comprises a plurality of second main surface-side gate structures arranged along a predetermined arrangement direction, and a first dense region in which three or more consecutive second main surface-side gate structures are arranged and a first sparse region in which three or more consecutive second main surface-side gate structures are arranged at a density lower than that in the first dense region are defined.

Power loss can be suppressed.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a cross-sectional view illustrating a configuration of a semiconductor device according to Embodiment 1;

FIG. 2 is a cross-sectional view illustrating a configuration of a semiconductor device according to Embodiment 2;

FIG. 3 is a cross-sectional view illustrating a configuration of a semiconductor device according to Embodiment 3;

FIG. 4 is a cross-sectional view illustrating a configuration of a semiconductor device according to Embodiment 4;

FIG. 5 is a cross-sectional view illustrating a configuration of a semiconductor device according to Embodiment 4;

FIG. 6 is a cross-sectional view illustrating a configuration of a semiconductor device according to Embodiment 5; and

FIG. 7 is a cross-sectional view illustrating a configuration of a semiconductor device according to Embodiment 6.

### DESCRIPTION OF THE PREFERRED EMBODIMENTS

Embodiments will be described below with reference to the accompanying drawings. Features described in Embodiments below are examples, and all the features are not necessarily required. In description made below, similar components in Embodiments bear the same or similar reference signs, and different components will mainly be described. In description made below, specific positions and directions, such as “upper”, “lower”, “left”, “right”, “front”, and “back”, may not necessarily match positions and directions in actual implementation.

A higher concentration in a portion than in another portion may mean that an average concentration in the portion is higher than an average concentration in the other portion, for example. In contrast, a lower concentration in a portion than in another portion may mean that an average concentration in the portion is lower than an average concentration in the other portion, for example. While description will be made below based on the assumption that a first conductivity type is an n type and a second conductivity type is a p type, the first conductivity type may be the p type and the second conductivity type may be the n type. In description made below, n means a lower n type impurity concentration than n, n⁺ means a higher n type impurity concentration than n, and p⁺ means a higher p type impurity concentration than p.

### Embodiment 1

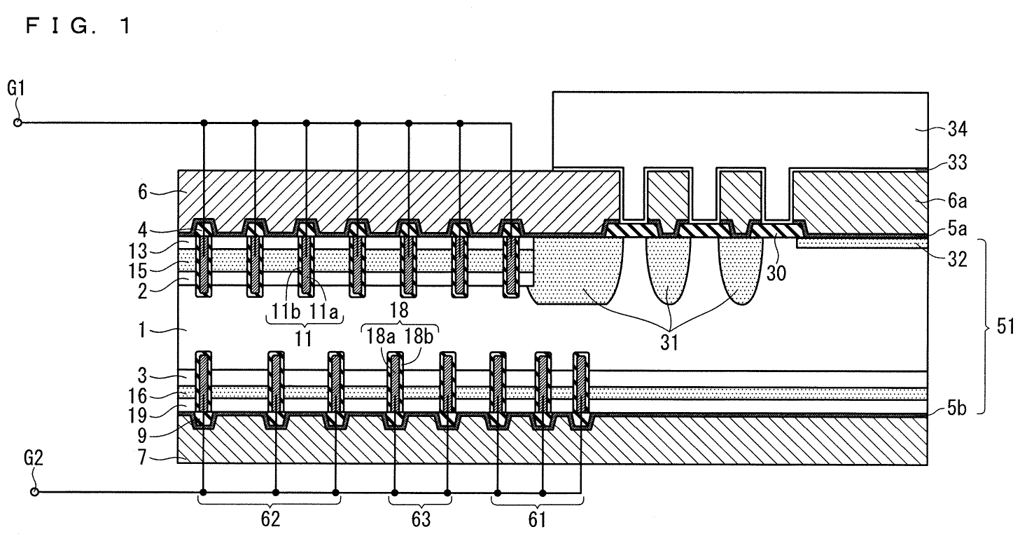

FIG. 1 is a cross-sectional view illustrating a configuration of a semiconductor device according to Embodiment 1. While the semiconductor device described below is an IGBT, the semiconductor device is not limited to the IGBT.

The semiconductor device in FIG. 1 includes a semiconductor substrate 51, interlayer insulating films 4 and 9, barrier metals 5a and 5b, an emitter electrode 6, a termination electrode 6a, a collector electrode 7, first active trench gates 11, second active trench gates 18, an insulating film 30, a semi-insulating film 33, and a termination protective film 34.

The semiconductor substrate 51 is a substrate having a first main surface (an upper surface in FIG. 1) and a second main surface (a lower surface in FIG. 1) opposite the first main surface. The semiconductor substrate 51 includes at least any one of a usual semiconductor wafer and an epitaxially grown layer. At least any one of A, B, C, . . . , and Z, for example, herein means any one of all combinations of one or more elements selected from the group of A, B, C, . . . , and Z.

The semiconductor substrate 51 may be formed of silicon (Si) as usual or may be formed of a wide bandgap semiconductor, such as silicon carbide (SiC), gallium nitride (GaN), gallium oxide (Ga₂O₃), and diamond. The semiconductor substrate 51 formed of the wide bandgap semiconductor enables stable operation at a high temperature and at a high voltage and a faster switching speed of the semiconductor device.

An active region on a left side in FIG. 1 and a termination region on a right side in FIG. 1 are defined in the semiconductor substrate 51. A semiconductor element, such as an IGBT, is provided in the active region, and a structure to hold a breakdown voltage in the active region is provided in the termination region. A configuration of the active region will be described, and then a configuration of the termination region will be described below.

### <Configuration of Active Region>

The semiconductor substrate 51 in the active region in FIG. 1 includes an n⁻ type drift layer 1, an n type carrier stored layer 2, an n type buffer layer 3, an n⁺ type source layer 13, a p type base layer 15, a p type collector layer 16, and an n⁺ type collector layer 19. The n type carrier stored layer 2 and the n type buffer layer 3 are not necessarily provided.

The n type drift layer 1 is provided between the first main surface and the second main surface of the semiconductor substrate 51. The n type carrier stored layer 2 is provided on a side closer to the first main surface of the n⁻ type drift layer 1. The p type base layer 15 as a base layer is provided on a side closer to the first main surface of the n⁻ type drift layer 1 via the n type carrier stored layer 2.

The n⁺ type source layer 13 as a source layer is provided on a side closer to the first main surface of the p type base layer 15. Although not illustrated, the p type base layer 15 extends toward the first main surface without providing the n⁺ type source layer 13 and is electrically connected to the emitter electrode 6 in cross section different from that in FIG. 1.

The first active trench gates 11 are first main surface-side gate structures including trench structures and are provided on a side closer to the first main surface. Each of the first active trench gates 11 includes a gate trench electrode 11a and a gate trench-insulating film 11b and is provided in a trench extending from an upper surface of the n⁺ type source layer 13 through the p type base layer 15 and the n type carrier stored layer 2 to the n⁻ type drift layer 1. The gate trench electrode 11a is provided over an inner surface of the trench via the gate trench-insulating film 11b and is electrically connected to an unillustrated gate pad via gate wiring G1. While the plurality of first active trench gates 11 are arranged along a predetermined arrangement direction (transverse direction in FIG. 1) in Embodiment 1, a single first active trench gate 11 may be provided.

The interlayer insulating films 4 are provided over the first active trench gates 11. The barrier metal 5a is provided over portions of the n⁺ type source layer 13 exposed from the interlayer insulating films 4. The barrier metal 5a contains metal, such as Ti, TiN, and TiSi. The barrier metal 5a is in ohmic contact with the n⁺ type source layer 13.

The emitter electrode 6 is insulated from the gate trench electrodes 11a by the interlayer insulating films 4 and is electrically connected to the n⁺ type source layer 13 via the barrier metal 5a. The emitter electrode 6 contains metal, such as aluminum and an aluminum alloy. The barrier metal 5a is not necessarily provided, and the emitter electrode 6 may directly be connected to the n⁺ type source layer 13.

A configuration provided on a side closer to the first main surface of the semiconductor substrate 51 in the active region has been described above. A configuration similar to the configuration is provided on a side closer to the second main surface of the semiconductor substrate 51 in the active region. The configuration provided on the side closer to the second main surface of the semiconductor substrate 51 in the active region will be described below.

The n type buffer layer 3 is provided on a side closer to the second main surface of the n type drift layer 1. The p type collector layer 16 as a first collector layer is provided on a side closer to the second main surface of the n⁻ type drift layer 1 via the n type buffer layer 3.

The n⁺ type collector layer 19 as a second collector layer is provided on a side closer to the second main surface of the p type collector layer 16. Although not illustrated, the p type collector layer 16 extends toward the second main surface without providing the n⁺ type collector layer 19 and is electrically connected to the collector electrode 7 in cross section different from that in FIG. 1.

The second active trench gates 18 are second main surface-side gate structures including trench structures and are provided on a side closer to the second main surface. Each of the second active trench gates 18 includes a gate trench electrode 18a and a gate trench-insulating film 18b and is provided in a trench extending from a lower surface of the n⁺ type collector layer 19 through the p type collector layer 16 and the n type buffer layer 3 to the n type drift layer 1. The gate trench electrode 18a is provided over an inner surface of the trench via the gate trench-insulating film 18b and is electrically connected to an unillustrated gate pad via gate wiring G2. The plurality of second active trench gates 18 are arranged along the above-mentioned arrangement direction (transverse direction in FIG. 1).

In Embodiment 1, a dense region 61 as a first dense region and a sparse region 62 as a first sparse region are defined for the plurality of second active trench gates 18. In the dense region 61, three or more consecutive second active trench gates 18 are arranged. In the sparse region 62, three or more consecutive second active trench gates 18 are arranged at a density lower than that in the dense region 61. For example, n consecutive second active trench gates 18 mean that, from among the plurality of second active trench gates 18 as arranged, a 1^{st} second active trench gate 18, a 2^{nd} second active trench gate 18 closest to the 1^{st} second active trench gate 18, a 3^{rd} second active trench gate 18 closest to the 2^{nd} second active trench gate 18 except for the 1^{st} second active trench gate 18, . . . , and an n^{th} second active trench gate 18 closest to an n−1^{th} second active trench gate 18 except for an n−2^{th} second active trench gate 18 are included. Being consecutive has the same meaning in description made below. A density means the number of three or more consecutive second active trench gates 18 per total spacing between the three or more consecutive second active trench gates 18.

As one example, in Embodiment 1, spacing between six or more second active trench gates 18 including the three or more second active trench gates 18 in the dense region 61 and the three or more second active trench gates 18 in the sparse region 62 monotonically increases from the dense region 61 to the sparse region 62. In an example of FIG. 1, spacing between six second active trench gates 18 including three second active trench gates 18 in the dense region 61 and three second active trench gates 18 in the sparse region 62 monotonically increases from the dense region 61 to the sparse region 62. As a result, the three second active trench gates 18 in the sparse region 62 are arranged at a lower density than the three second active trench gates 18 in the dense region 61.

In the example of FIG. 1, the dense region 61 is defined on a side closer to an outer periphery of the semiconductor substrate 51, that is, on a side closer to the termination region. As in the example of FIG. 1, an intermediate region 63 in which the density is lower than that in the dense region 61 and is higher than that in the sparse region 62 may be provided. Spacing between the plurality of second active trench gates 18 in the dense region 61, the intermediate region 63, and the sparse region 62 may monotonically increase from the dense region 61 through the intermediate region 63 to the sparse region 62.

The interlayer insulating films 9 are provided over the second active trench gates 18 (on a side opposite the semiconductor substrate 51 with respect to the second active trench gates 18). The collector electrode 7 is insulated from the gate trench electrodes 18a by the interlayer insulating films 9 and is electrically connected to the n⁺ type collector layer 19 via the barrier metal 5b similar to the barrier metal 5a. The barrier metal 5b is not necessarily provided, and the collector electrode 7 may directly be connected to the n⁺ type collector layer 19.

### <Configuration of Termination Region>

The semiconductor substrate 51 in the termination region in FIG. 1 includes the n⁻ type drift layer 1, the n type buffer layer 3, the p type collector layer 16, the n⁺ type collector layer 19, p type termination well layers 31, and a p⁺ contact layer 32.

The p type termination well layers 31 and the p⁺ contact layer 32 are selectively provided on a side closer to the first main surface of the n⁻ type drift layer 1. In Embodiment 1, the p type termination well layers 31 are connected to the p type base layer 15, and lower ends of the p type termination well layers 31 are located below a lower end of the n type carrier stored layer 2. The p⁺ contact layer 32 is provided at an end of the semiconductor substrate 51.

The insulating film 30 is provided over portions of the n⁻ type drift layer 1 in which the p type termination well layers 31 and the p⁺ contact layer 32 are not provided. The barrier metal 5a is provided over portions of the p type termination well layers 31 and the p⁺ contact layer 32 exposed from the insulating film 30. The termination electrode 6a is electrically connected to the p⁺ contact layer 32 via the barrier metal 5a. The barrier metal 5a is not necessarily provided, and the termination electrode 6a may directly be connected to the p⁺ contact layer 32.

The semi-insulating film 33 is provided over the emitter electrode 6 and the termination electrode 6a. The barrier metal 5a in the termination region is separated by the semi-insulating film 33. The semi-insulating film 33 contains a semi-insulating silicon nitride film (sinSiN), for example. The termination protective film 34 is provided to cover the semi-insulating film 33.

On a side closer to the second main surface in the termination region, the n type buffer layer 3, the p type collector layer 16, the n⁺ type collector layer 19, the barrier metal 5b, and the collector electrode 7 are provided as in the active region. The barrier metal 5b, however, is not necessarily provided, and the n⁺ type collector layer 19 may not be provided in the termination region depending on a specification of the semiconductor device.

As a method of manufacturing the semiconductor device according to Embodiment 1, a general process of manufacturing an IGBT is used. A process performed on the second main surface of the semiconductor substrate may be the same as or may be different as appropriate from a process performed on the first main surface of the semiconductor substrate.

### <Operation>

When a positive bias is applied from the unillustrated gate pad to the gate trench electrodes 11a via the gate wiring G1, portions of the p type base layer 15 adjacent to the first active trench gates 11 are reversed to the n type to form a first conductive channel. That is to say, the first active trench gates 11 are configured to control the first conductive channel in the p type base layer 15.

Similarly, when a positive bias is applied from the unillustrated gate pad to the gate trench electrodes 18a via the gate wiring G2, portions of the p type collector layer 16 adjacent to the second active trench gates 18 are reversed to the n type to form a second conductive channel. That is to say, the second active trench gates 18 are configured to control the second conductive channel in the p type collector layer 16.

When the first conductive channel is formed, and a positive voltage is applied to the collector electrode 7, the configuration in FIG. 1 as a whole can serve as an IGBT regardless of whether the second conductive channel is formed. On the other hand, in the semiconductor device according to Embodiment 1, when a load current flowing from the second main surface to the first main surface is zero or in a reverse direction, the second conductive channel is formed in the p type collector layer 16 by application of a positive bias to the second active trench gates 18. According to such a configuration, when the second conductive channel is formed, and a negative voltage is applied to the collector electrode 7, the configuration in FIG. 1 as a whole can serve as a freewheeling diode regardless of whether the first conductive channel is formed.

### Summary of Embodiment 1

In the sparse region 62, a region farther from the second active trench gates 18 has a greater area, so that the sparse region 62 as a whole tends to serve as an IGBT into which hole carriers are injected. On the other hand, in the dense region 61, a region farther from the second active trench gates 18 has a smaller area, so that the dense region 61 as a whole tends to serve as a diode into which electrons are injected. Conventional technology has a problem of deterioration of power loss as only one of the dense region 61 and the sparse region 62 is provided, or each region is small so that it is difficult to inject carriers into the region.

In contrast, in Embodiment 1, the dense region 61 and the sparse region 62 are defined for the plurality of second active trench gates 18, and three or more second active trench gates 18 are arranged in each of the dense region 61 and the sparse region 62.

According to such a configuration, the dense region 61 and the sparse region 62 can be widened to facilitate injection of respective carriers into the regions, so that power loss can be suppressed. A region in which the dense region 61 and the sparse region 62 do not interfere with each other can be larger, so that power loss can be suppressed also from this perspective.

In Embodiment 1, the dense region 61 is defined on the side closer to the outer periphery of the semiconductor substrate 51, that is, on the side closer to the termination region. According to such a configuration, when a structure having a predominance of the n type (a structure including the n type buffer layer 3, the p type collector layer 16, and the n⁺ type collector layer 19 as in FIG. 1) is provided on a side closer to the second main surface in the termination region, interference of the structure with the dense region 61 can be suppressed.

In Embodiment 1, the second active trench gates 18 are provided as the second main surface-side gate structures including the trench structures. According to such a configuration, spacing between the second active trench gates 18 can be reduced, so that a gradient of the density can easily be provided.

The widest spacing between the second active trench gates 18 is preferably greater than ⅓ of a thickness of the semiconductor substrate 51, and the narrowest spacing between the second active trench gates 18 is preferably smaller than ¼ of the thickness of the semiconductor substrate. According to such a configuration, suppression in power loss can be enhanced on a simulation.

### Embodiment 2

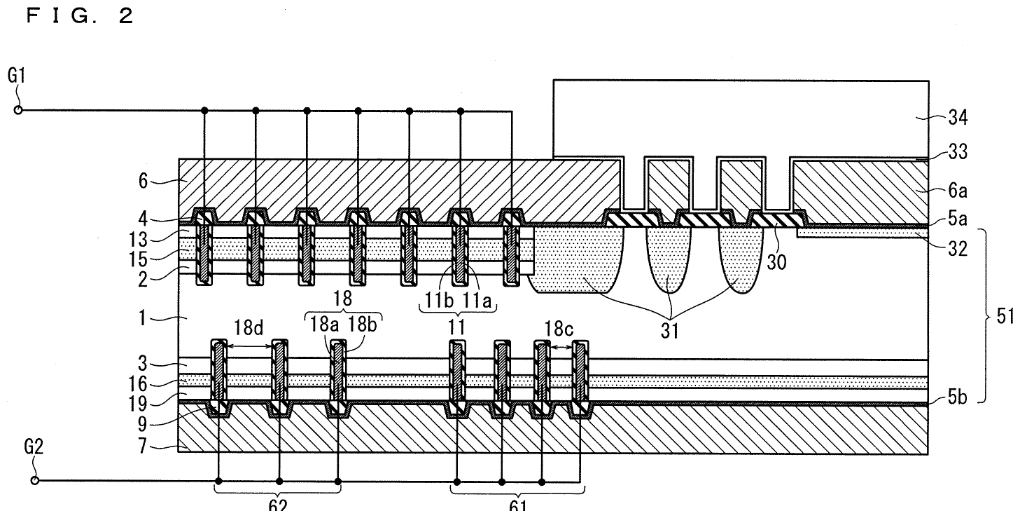

FIG. 2 is a cross-sectional view illustrating a configuration of a semiconductor device according to Embodiment 2. In Embodiment 2, the dense region 61 and the sparse region 62 are defined for the plurality of second active trench gates 18 as in Embodiment 1.

As one example, in Embodiment 2, three or more second active trench gates 18 in the dense region 61 are arranged with first spacing 18c, and three or more second active trench gates 18 in the sparse region 62 are arranged with second spacing 18d greater than the first spacing 18c. In an example of FIG. 2, four second active trench gates 18 in the dense region 61 are arranged with the first spacing 18c, and three second active trench gates 18 in the sparse region 62 are arranged with the second spacing 18d greater than the first spacing 18c. In Embodiment 2, the dense region 61 is defined on the side closer to the outer periphery of the semiconductor substrate 51, that is, on the side closer to the termination region as in Embodiment 1.

Although not illustrated, an intermediate region in which the density is lower than that in the dense region 61 and is higher than that in the sparse region 62 may be provided in Embodiment 2 as in Embodiment 1. Specifically, an intermediate region in which a plurality of second active trench gates 18 are arranged with third spacing greater than the first spacing 18c and smaller than the second spacing 18d may be provided.

### Summary of Embodiment 2

According to the semiconductor device according to Embodiment 2 as described above, three or more second active trench gates 18 are arranged in each of the dense region 61 and the sparse region 62 as in Embodiment 1, so that power loss can be suppressed.

In Embodiment 2, the dense region 61 is defined on the side closer to the outer periphery of the semiconductor substrate 51, that is, on the side closer to the termination region as in Embodiment 1. According to such a configuration, when the structure having the predominance of the n type is provided on the side closer to the second main surface in the termination region, interference of the structure with the dense region 61 can be suppressed.

### Embodiment 3

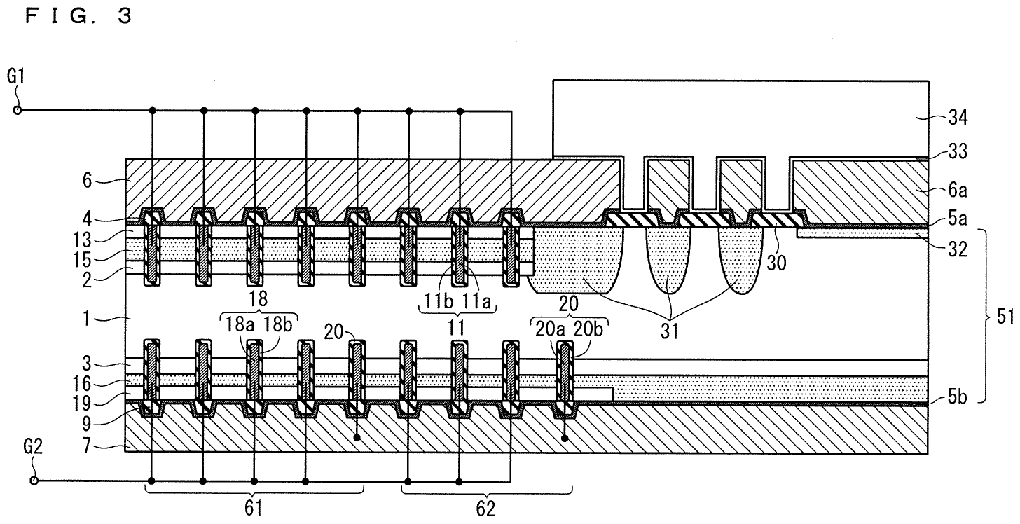

FIG. 3 is a cross-sectional view illustrating a configuration of a semiconductor device according to Embodiment 3. In Embodiment 3, dummy trench gates 20 as second main surface-side dummy gate structures not serving as the second active trench gates 18 are provided on a side closer to the second main surface. Each of the dummy trench gates 20 includes a dummy trench electrode 20a and a dummy trench-insulating film 20b and is provided in a trench extending from the lower surface of the n⁺ type collector layer 19 through the p type collector layer 16 and the n type buffer layer 3 to the n type drift layer 1. The dummy trench electrode 20a is provided over an inner surface of the trench via the dummy trench-insulating film 20b and is electrically connected not to the gate wiring G2 but to the collector electrode 7.

In Embodiment 3, the dense region 61 and the sparse region 62 are defined for the plurality of second active trench gates 18 as in Embodiment 1. As one example, in Embodiment 3, a ratio of the second active trench gates 18 in the dense region 61 is greater than a ratio of the second active trench gates 18 in the sparse region 62.

The ratio of the second active trench gates 18 in the dense region 61 is the number of three or more second active trench gates 18 in the dense region 61 per total number of three or more second active trench gates 18 and a dummy trench gate 20 in the dense region 61. The ratio of the second active trench gates 18 in the sparse region 62 is the number of three or more second active trench gates 18 in the sparse region 62 per total number of three or more second active trench gates 18 and a dummy trench gate 20 in the sparse region 62.

In an example of FIG. 3, the ratio of the second active trench gates 18 in the sparse region 62 is ¾, and the ratio of the second active trench gates 18 in the dense region 61 is ⅘. In the example of FIG. 3, a plurality of trench gates including the plurality of second active trench gates 18 and the plurality of dummy trench gates 20 are arranged at regular intervals for convenience of description. The plurality of trench gates, however, may not be arranged at regular intervals as long as the density is lower in the sparse region 62 than in the dense region 61.

Although not illustrated, an intermediate region in which the density is lower than that in the dense region 61 and is higher than that in the sparse region 62 may be provided in Embodiment 3 as in Embodiment 1. Specifically, an intermediate region in which the ratio of the second active trench gates 18 is smaller than that in the dense region 61 and is greater than that in the sparse region 62 may be provided.

In Embodiment 3, the sparse region 62 is defined on a side closer to the outer periphery of the semiconductor substrate 51, that is, on a side closer to the termination region. On the side closer to the second main surface in the termination region, the n type buffer layer 3 and the p type collector layer 16 are provided without providing the n⁺ type collector layer 19.

### Summary of Embodiment 3

According to the semiconductor device according to Embodiment 3 as described above, three or more second active trench gates 18 are arranged in each of the dense region 61 and the sparse region 62 as in Embodiment 1, so that power loss can be suppressed.

In Embodiment 3, the sparse region 62 is defined on the side closer to the outer periphery of the semiconductor substrate 51, that is, on the side closer to the termination region. According to such a configuration, when a structure having a predominance of the p type (a structure including the n type buffer layer 3 and the p type collector layer 16 as in FIG. 3) is provided on the side closer to the second main surface in the termination region, interference of the structure with the sparse region 62 can be suppressed.

### Embodiment 4

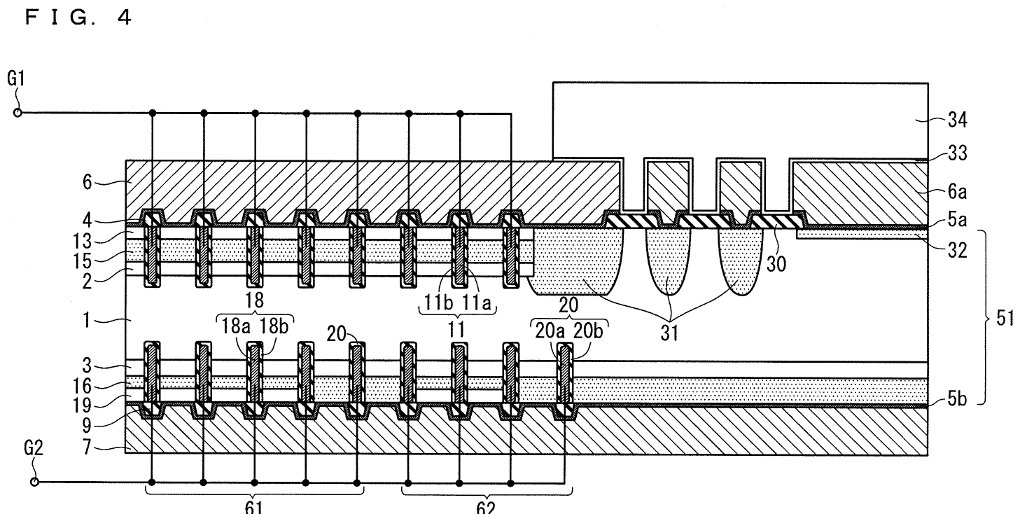

FIG. 4 is a cross-sectional view illustrating a configuration of a semiconductor device according to Embodiment 4. In Embodiment 4, the dummy trench gates 20 not serving as the second active trench gates 18 are provided on a side closer to the second main surface as in Embodiment 3. The dummy trench gates 20 according to Embodiment 4, however, are not electrically connected to the collector electrode 7 and are not in contact with the n⁺ type collector layer 19. In Embodiment 4, the ratio of the second active trench gates 18 in the dense region 61 is greater than the ratio of the second active trench gates 18 in the sparse region 62 as in Embodiment 3.

### Summary of Embodiment 4

According to the semiconductor device according to Embodiment 4 as described above, three or more second active trench gates 18 are arranged in each of the dense region 61 and the sparse region 62 as in Embodiment 1, so that power loss can be suppressed.

In Embodiment 4, the sparse region 62 is defined on the side closer to the outer periphery of the semiconductor substrate 51, that is, on the side closer to the termination region as in Embodiment 3. According to such a configuration, when the structure having the predominance of the p type is provided on the side closer to the second main surface in the termination region, interference of the structure with the sparse region 62 can be suppressed.

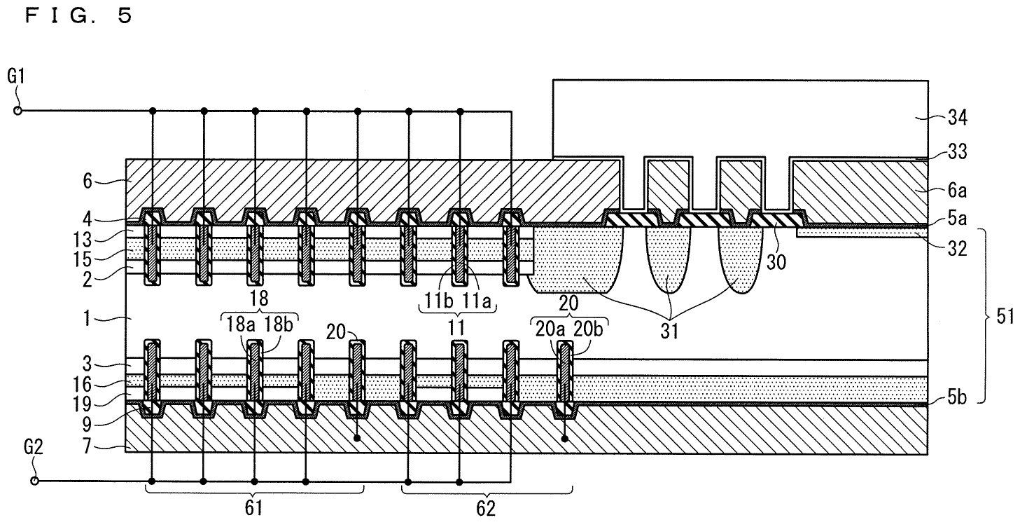

As illustrated in FIG. 5, the dummy trench gates 20 according to Embodiment 4 may electrically be connected to the collector electrode 7 as in Embodiment 3. Power loss can be suppressed even with such a configuration.

### Embodiment 5

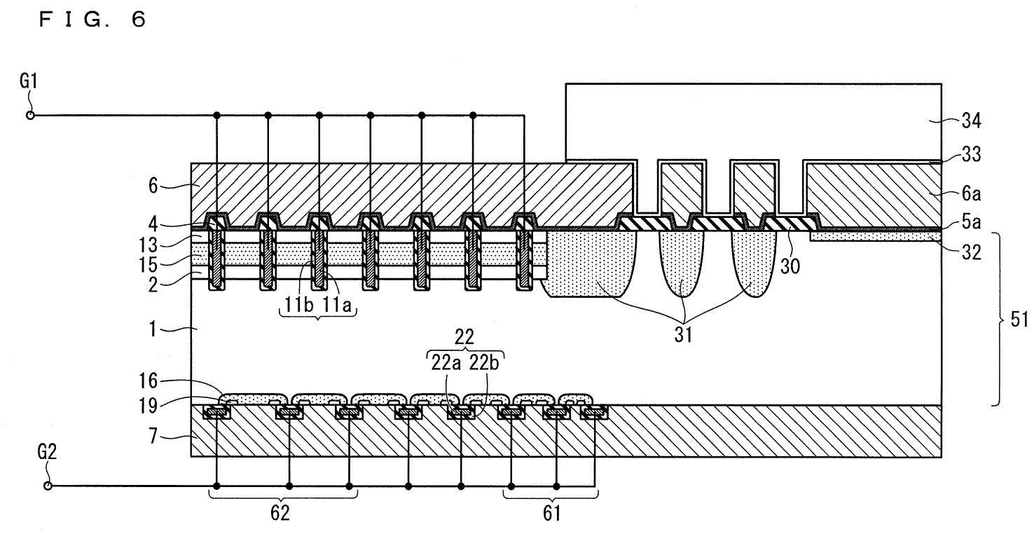

FIG. 6 is a cross-sectional view illustrating a configuration of a semiconductor device according to Embodiment 5. The configuration in which the second active trench gates 18 are provided as the second main surface-side gate structures including the trench structures has been described so far. In Embodiment 5, planar gates 22 are provided not as the second main surface-side gate structures including the trench structures but as second main surface-side gate structures including planar structures.

In Embodiment 5, the p type collector layer 16 is selectively provided on a side closer to the second main surface of the n⁻ type drift layer 1. The n⁺ type collector layer 19 is selectively provided on a side closer to the second main surface of the p type collector layer 16 so that the n⁺ type collector layer 19 and the n⁻ type drift layer 1 sandwich the p type collector layer 16.

Each of the planar gates 22 includes a gate electrode 22a and a gate insulating film 22b. The gate electrode 22a is provided over the p type collector layer 16 sandwiched between the n⁻ type drift layer 1 and the n⁺ type collector layer 19 via the gate insulating film 22b. When a positive bias is applied to the gate electrode 22a, portions of the p type collector layer 16 adjacent to the planar gates 22 are reversed to the n type to form a second conductive channel.

In Embodiment 5, the dense region 61 and the sparse region 62 are defined for the plurality of planar gates 22 as in Embodiment 1. In the dense region 61, three or more consecutive planar gates 22 are arranged. In the sparse region 62, three or more consecutive planar gates 22 are arranged at a density lower than that in the dense region 61. Spacing between the planar gates 22 corresponds to spacing between the gate electrodes 22a. The density means the number of three or more consecutive planar gates 22 per total spacing between the three or more consecutive planar gates 22.

As one example, in Embodiment 5, spacing between six or more planar gates 22 including the three or more planar gates 22 in the dense region 61 and the three or more planar gates 22 in the sparse region 62 monotonically increases from the dense region 61 to the sparse region 62.

### Summary of Embodiment 5

According to the semiconductor device according to Embodiment 5 as described above, three or more planar gates 22 are arranged in each of the dense region 61 and the sparse region 62 as in Embodiment 1, so that power loss can be suppressed.

In Embodiment 5, the planar gates 22 are provided as the second main surface-side gate structures including the planar structures. According to such a configuration, when it is difficult to provide the trench structures on the side closer to the second main surface, the dense region 61 and the sparse region 62 can be provided by providing the planar structures on the side closer to the second main surface.

Embodiment 5 is applicable not only to Embodiment 1 but also to Embodiments 2 to 4. While the configuration in which the first active trench gates 11 are provided as the first main surface-side gate structures including the trench structures has been described in Embodiments 1 to 5, first main surface-side gate structures including the planar structures may be provided.

### Embodiment 6

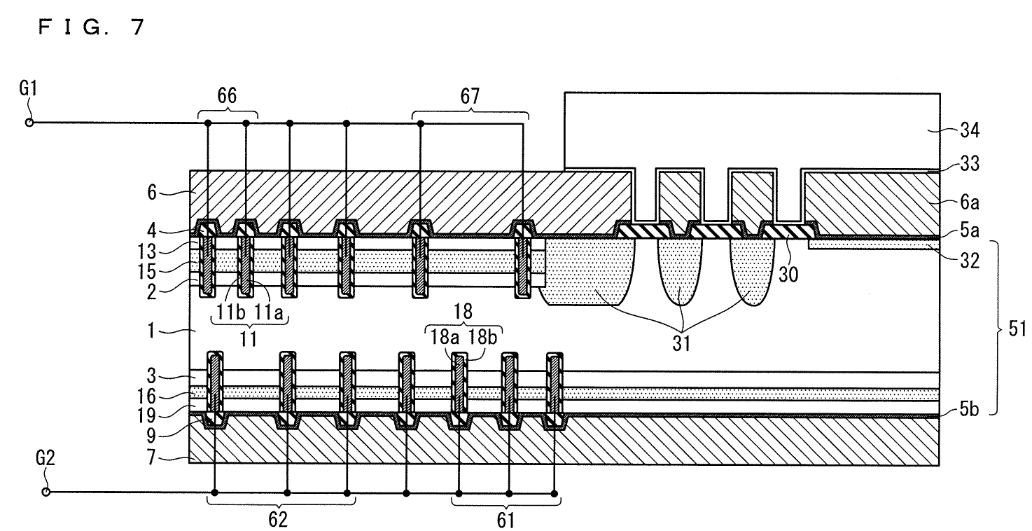

FIG. 7 is a cross-sectional view illustrating a configuration of a semiconductor device according to Embodiment 6. In Embodiment 6, a dense region 66 as a second dense region and a sparse region 67 as a second sparse region are defined for the plurality of first active trench gates 11. In the dense region 66, two or more consecutive first active trench gates 11 are arranged. In the sparse region 67, two or more consecutive first active trench gates 11 are arranged at a density lower than that in the dense region 66.

The density means the number of two or more consecutive first active trench gates 11 per total spacing between the two or more consecutive first active trench gates 11. In Embodiment 6, the sparse region 67 is provided on a side closer to the first main surface of the dense region 61, and the dense region 66 is provided on a side closer to the first main surface of the sparse region 62.

### Summary of Embodiment 6

The dense region 66 tends to serve as an IGBT in contrast to the dense region 61 that tends to serve as a diode. On the other hand, the sparse region 67 tends to serve as a diode in contrast to the sparse region 62 that tends to serve as an IGBT. In the semiconductor device according to Embodiment 6, the dense region 66 and the sparse region 67 are defined for the plurality of first active trench gates 11, the sparse region 67 is provided on the side closer to the first main surface of the dense region 61, and the dense region 66 is provided on the side closer to the first main surface of the sparse region 62.

According to such a configuration, a diode function can be enhanced in the dense region 61 and the sparse region 67, and an IGBT function can be enhanced in the sparse region 62 and the dense region 66. Embodiment 6 is applicable not only to Embodiment 1 but also to Embodiments 2 to 5.

In the present disclosure in English, indefinite articles “a” and “an” mean one or more. Thus, “a”, “an”, “one or more”, and “at least one” can be used interchangeably.

Embodiments and modifications can freely be combined with each other and can be modified or omitted as appropriate.

Various aspects of the present disclosure will collectively be described below as appendices.

### APPENDIX 1

A semiconductor device comprising:
a semiconductor substrate having a first main surface and a second main surface opposite the first main surface, the semiconductor substrate including a drift layer of a first conductivity type between the first main surface and the second main surface;
a base layer of a second conductivity type provided on a side closer to the first main surface of the drift layer;
a source layer of the first conductivity type provided on a side closer to the first main surface of the base layer;
a first main surface-side gate structure provided in the first main surface to control a first conductive channel in the base layer;
a first collector layer of the second conductivity type provided on a side closer to the second main surface of the drift layer;
a second collector layer of the first conductivity type provided on a side closer to the second main surface of the first collector layer; and
a second main surface-side gate structure provided in the second main surface to control a second conductive channel in the first collector layer, wherein
the second main surface-side gate structure comprises a plurality of second main surface-side gate structures arranged along a predetermined arrangement direction, and
a first dense region in which three or more consecutive second main surface-side gate structures are arranged and a first sparse region in which three or more consecutive second main surface-side gate structures are arranged at a density lower than that in the first dense region are defined.

### APPENDIX 2

The semiconductor device according to Appendix 1, wherein
spacing between six or more second main surface-side gate structures including the three or more second main surface-side gate structures in the first dense region and the three or more second main surface-side gate structures in the first sparse region monotonically increases from the first dense region to the first sparse region.

### APPENDIX 3

The semiconductor device according to Appendix 1, wherein
the three or more second main surface-side gate structures in the first dense region are arranged with first spacing, and
the three or more second main surface-side gate structures in the first sparse region are arranged with second spacing greater than the first spacing.

### APPENDIX 4

The semiconductor device according to Appendix 1, further comprising:
a collector electrode electrically connected to the second collector layer; and
a second main surface-side dummy gate structure provided on a side closer to the second main surface and electrically connected to the collector electrode.

### APPENDIX 5

The semiconductor device according to Appendix 1, further comprising
a second main surface-side dummy gate structure provided on a side closer to the second main surface and being not in contact with the second collector layer.

### APPENDIX 6

The semiconductor device according to Appendix 1, further comprising:
a collector electrode electrically connected to the second collector layer; and
a second main surface-side dummy gate structure provided on a side closer to the second main surface, electrically connected to the collector electrode, and not being in contact with the second collector layer.

### APPENDIX 7

The semiconductor device according to any one of Appendices 4 to 6, wherein
the number of the three or more second main surface-side gate structures in the first dense region per total number of the three or more second main surface-side gate structures and the second main surface-side dummy gate structure in the first dense region is greater than the number of the three or more second main surface-side gate structures in the first sparse region per total number of the three or more second main surface-side gate structures and the second main surface-side dummy gate structure in the first sparse region.

### APPENDIX 8

The semiconductor device according to any one of Appendices 1 to 7, wherein
the first dense region is defined on a side closer to an outer periphery of the semiconductor substrate.

### APPENDIX 9

The semiconductor device according to any one of Appendices 1 to 7, wherein
the first sparse region is defined on a side closer to an outer periphery of the semiconductor substrate.

### APPENDIX 10

The semiconductor device according to any one of Appendices 1 to 9, wherein
the second main surface-side gate structures include trench structures.

### APPENDIX 11

The semiconductor device according to any one of Appendices 1 to 9, wherein
the second main surface-side gate structures include planar structures.

### APPENDIX 12

The semiconductor device according to any one of Appendices 1 to 11, wherein
the widest spacing between the second main surface-side gate structures is greater than ⅓ of a thickness of the semiconductor substrate, and
the narrowest spacing between the second main surface-side gate structures is smaller than ¼ of the thickness of the semiconductor substrate.

### APPENDIX 13

The semiconductor device according to any one of Appendices 1 to 12, wherein
the first main surface-side gate structure comprises a plurality of first main surface-side gate structures arranged along the arrangement direction, and
a second dense region in which two or more consecutive first main surface-side gate structures are arranged and a second sparse region in which two or more consecutive first main surface-side gate structures are arranged at a density lower than that in the second dense region are defined.

### APPENDIX 14

The semiconductor device according to Appendix 13, wherein
the second sparse region is provided on a side closer to the first main surface of the first dense region, and
the second dense region is provided on a side closer to the first main surface of the first sparse region.

### APPENDIX 15

The semiconductor device according to any one of Appendices 1 to 14, wherein
when a load current flowing from the second main surface to the first main surface is zero or in a reverse direction, the second conductive channel is formed in the first collector layer by application of a positive bias to the second main surface-side gate structures.

While the disclosure has been shown and described in detail, the foregoing description is in all aspects illustrative and not restrictive. It is therefore understood that numerous modifications and variations can be devised.

What is claimed is:

1. A semiconductor device comprising:
a semiconductor substrate having a first main surface and a second main surface opposite the first main surface, the semiconductor substrate including a drift layer of a first conductivity type between the first main surface and the second main surface;
a base layer of a second conductivity type provided on a side closer to the first main surface of the drift layer;
a source layer of the first conductivity type provided on a side closer to the first main surface of the base layer;
a first main surface-side gate structure provided in the first main surface to control a first conductive channel in the base layer;
a first collector layer of the second conductivity type provided on a side closer to the second main surface of the drift layer;
a second collector layer of the first conductivity type provided on a side closer to the second main surface of the first collector layer; and
a second main surface-side gate structure provided in the second main surface to control a second conductive channel in the first collector layer, wherein
the second main surface-side gate structure comprises a plurality of second main surface-side gate structures arranged along a predetermined arrangement direction, and
a first dense region in which three or more consecutive second main surface-side gate structures are arranged and a first sparse region in which three or more consecutive second main surface-side gate structures are arranged at a density lower than that in the first dense region are defined.

2. The semiconductor device according to claim 1, wherein
spacing between six or more second main surface-side gate structures including the three or more second main surface-side gate structures in the first dense region and the three or more second main surface-side gate structures in the first sparse region monotonically increases from the first dense region to the first sparse region.

3. The semiconductor device according to claim 1, wherein
the three or more second main surface-side gate structures in the first dense region are arranged with first spacing, and
the three or more second main surface-side gate structures in the first sparse region are arranged with second spacing greater than the first spacing.

4. The semiconductor device according to claim 1, further comprising:
a collector electrode electrically connected to the second collector layer; and
a second main surface-side dummy gate structure provided on a side closer to the second main surface and electrically connected to the collector electrode.

5. The semiconductor device according to claim 1, further comprising
a second main surface-side dummy gate structure provided on a side closer to the second main surface and being not in contact with the second collector layer.

6. The semiconductor device according to claim 1, further comprising:
a collector electrode electrically connected to the second collector layer; and
a second main surface-side dummy gate structure provided on a side closer to the second main surface, electrically connected to the collector electrode, and not being in contact with the second collector layer.

7. The semiconductor device according to claim 4, wherein
the number of the three or more second main surface-side gate structures in the first dense region per total number of the three or more second main surface-side gate structures and the second main surface-side dummy gate structure in the first dense region is greater than the number of the three or more second main surface-side gate structures in the first sparse region per total number of the three or more second main surface-side gate structures and the second main surface-side dummy gate structure in the first sparse region.

8. The semiconductor device according to claim 1, wherein
the first dense region is defined on a side closer to an outer periphery of the semiconductor substrate.

9. The semiconductor device according to claim 1, wherein
the first sparse region is defined on a side closer to an outer periphery of the semiconductor substrate.

10. The semiconductor device according to claim 1, wherein
the second main surface-side gate structures include trench structures.

11. The semiconductor device according to claim 1, wherein
the second main surface-side gate structures include planar structures.

12. The semiconductor device according to claim 1, wherein
the widest spacing between the second main surface-side gate structures is greater than ⅓ of a thickness of the semiconductor substrate, and
the narrowest spacing between the second main surface-side gate structures is smaller than ¼ of the thickness of the semiconductor substrate.

13. The semiconductor device according to claim 1, wherein
the first main surface-side gate structure comprises a plurality of first main surface-side gate structures arranged along the arrangement direction, and
a second dense region in which two or more consecutive first main surface-side gate structures are arranged and a second sparse region in which two or more consecutive first main surface-side gate structures are arranged at a density lower than that in the second dense region are defined.

14. The semiconductor device according to claim 13, wherein
the second sparse region is provided on a side closer to the first main surface of the first dense region, and
the second dense region is provided on a side closer to the first main surface of the first sparse region.

15. The semiconductor device according to claim 1, wherein
when a load current flowing from the second main surface to the first main surface is zero or in a reverse direction, the second conductive channel is formed in the first collector layer by application of a positive bias to the second main surface-side gate structures.
